(19) United States
(12) Patent Application Publication
(10) Pub. No.: US 2026/0107378 A1
(43) Pub. Date: Apr. 16, 2026

(54) MOTOR DRIVING CIRCUIT SUBSTRATE, MOTOR, AND PUMP DEVICE

(71) Applicant: NIDEC INSTRUMENTS CORPORATION, Nagano (JP)

(72) Inventors: Satoshi TANIMURA, Nagano (JP); Toshiyuki KARASAWA, Nagano (JP)

(73) Assignee: NIDEC INSTRUMENTS CORPORATION, Nagano (JP)

(21) Appl. No.: 19/114,459

(22) PCT Filed: Sep. 8, 2023
(86) PCT No.: PCT/JP2023/032879

§ 371 Date: Mar. 23, 2025

(30) Foreign Application Priority Data
Sep. 30, 2022 (JP) 2022-158069

(51) Int. Cl. H05K 1/02; H02K 11/00; H02K 11/02; H02K 11/33; H02K 11/40

(52) U.S. Cl. CPC H05K 1/0298; H02K 11/0094; H02K 11/02; H02K 11/33; H02K 11/40; H02K 2211/03; H05K 2201/09345; H05K 2201/095; H05K 2201/10015; H05K 2201/1003; H05K 2201/10053

(57) ABSTRACT

In a multilayer substrate including a motor drive circuit, a second conductive layer being a common ground pattern is formed over a substrate entire region in a second layer. In a third layer, a third conductive layer being the common ground pattern is formed to surround an outer periphery of a power-related circuit by an entire periphery of the third conductive layer. In the fourth layer, a fourth conductive layer being the common ground pattern is formed to surround the outer periphery of the power-related circuit by an entire periphery of the fourth conductive layer. The third conductive layer includes a noise guard portion extending along the outer periphery of the power-related circuit to a substrate outer edge. The noise guard portion is connected to the second conductive layer and the fourth conductive layer by multiple through holes arranged on the substrate outer edge to surround the power-related circuit.

### TECHNICAL FIELD

The present invention relates to a motor drive circuit substrate, a motor, and a pump device.

### BACKGROUND ART

A motor drive circuit includes a signal-related circuit including a control element, and a power-related circuit including a switching element that outputs a drive current. In a case where a signal-related circuit and a power-related circuit are mounted on a single substrate on which a motor drive circuit is to be mounted, it is required that the circuits be mounted at high density on the substrate. Thus, a multilayer substrate is used in which a plurality of layers, each having a wiring pattern and a ground pattern included in the circuits, are laminated with insulating layers interposed therebetween. Patent Literature 1 describes such a type of multilayer substrate.

### CITATION LIST

### Patent Literature

[Patent Literature 1] Japanese Patent Application Laid-open No. 2004-363347

### SUMMARY OF THE INVENTION

### Problems to be Solved by the Invention

In recent years, electromagnetic compatibility (EMC) has been required for a substrate on which a motor drive circuit is mounted. EMC refers to the compatibility of electromagnetic interference (EMI), which is emission or a phenomenon of electromagnetic energy radiation, and electromagnetic susceptibility (EMS), which is immunity or the ability to operate without performance degradation or malfunction due to external electromagnetic energy.

For an EMC countermeasure for a motor drive circuit substrate, in particular an EMI (emission) countermeasure, it has been proposed to add a common mode coil to the motor drive circuit. However, the addition of new parts results in increased costs.

In Patent Literature 1, for an EMI countermeasure, conductive shields to cover the ends of the multilayer substrate are formed to reduce noise radiation from the ends of the substrate to the outside. The shields connect the ends of ground layers disposed to sandwich a signal layer, a power source layer, and an insulating layer.

However, in Patent Literature 1, the layers in which circuit patterns are formed are separated from the ground layers as completely separate layers, and the shields are formed to connect the ends of the ground layers. This results in an increased number of layers in the multilayer substrate and requires processes not included in conventional manufacturing processes. As a result, the costs increase compared to conventional multilayer substrates. Furthermore, the drive circuit includes a related circuit and a power-related circuit, and noise radiation is mostly radiated from the power-related circuit through which a high current flows, but Patent Literature 1 does not take into consideration the arrangement of the signal-related circuit and the power-related circuit within the multilayer substrate. Therefore, it is hard to say that the arrangement of the shields is efficient, which also leads to increased costs.

In view of the above problems, an object of the present invention is to improve the EMC performance and suppress cost increases in a motor drive circuit substrate in which a signal-related circuit and a power-related circuit are mounted in the single substrate.

### Means for Solving the Problem

To solve the above problems, the present invention provides a motor drive circuit substrate including a motor drive circuit disposed in a multilayer substrate, the motor drive circuit including a power-related circuit including a switching element that outputs a drive current, and a signal-related circuit including a control element that supplies a signal to the switching element, in which in the multilayer substrate, a common ground pattern is provided by integrating a ground pattern for the power-related circuit and a ground pattern for the signal-related circuit, the multilayer substrate includes four layers stacked in an order of a first layer, a second layer, a third layer, and a fourth layer, the common ground pattern includes a second conductive layer provided in the second layer, a third conductive layer provided in the third layer, and a fourth conductive layer provided in the fourth layer, the first layer includes at least the control element mounted therein, the second layer includes the second conductive layer formed over a substrate entire region, the third layer includes a third layer circuit including the power-related circuit formed therein and the third conductive layer formed therein to surround an outer periphery of the third layer circuit by an entire periphery of the third conductive layer, the fourth layer includes a fourth layer circuit including the power-related circuit formed therein and the fourth conductive layer formed therein to surround an outer periphery of the fourth layer circuit by an entire periphery of the fourth conductive layer, the third conductive layer includes a noise guard portion extending along an outer periphery of the power-related circuit, and the noise guard portion is connected to the second conductive layer and the fourth conductive layer by a plurality of through holes arranged to surround the power-related circuit.

According to the present invention, the motor drive circuit can be mounted at high density in the multilayer substrate. Since the ground patterns for the signal-related circuit and the power-related circuit are integrated to form the common ground pattern, it is possible to provide a continuous, integrated common ground pattern over a wide area. The common ground pattern is provided over the entire region of the substrate in the second layer of the multilayer substrate, surrounds the third layer circuit by the entire periphery of the common ground pattern in the third layer, and is provided over a wide area surrounding the fourth layer circuit by the entire periphery of the common ground pattern in the fourth layer. Therefore, it is possible to block noise radiation from the circuits provided in the layers to the outside. In particular, in the third layer, the outer periphery of the power-related circuit is surrounded by the common ground pattern (noise guard portion) to prevent any gaps in the circumferential direction, and is connected to the common ground pattern of the upper and lower layers (second and fourth layers) by through holes disposed to surround the power-related circuit, and thus, noise radiation from the power-related circuit is effectively suppressed. Therefore, the motor drive circuit substrate has excellent EMC performance. The effect of suppressing noise radiation is enhanced by the layout of the patterns and through holes on the substrate without adding any parts, and as a result, an increase in costs is suppressed.

In the present invention, it is preferable that: a plurality of terminal holes into which a plurality of terminals for external connection are fitted are arranged along a substrate outer edge in a first region on one side with respect to a center of the multilayer substrate; the power-related circuit in the third layer circuit is disposed in a second region on the side opposite to the first region with respect to the center of the multilayer substrate; the noise guard portion extends along a substrate outer edge of the second region; both ends of the noise guard portion are connected to portions of the third conductive layer formed in the first region; and the plurality of through holes are arranged along the substrate outer edge of the second region. With such a configuration, the common ground pattern can be provided over a wide area in the first region. In the second region, a space on the outer periphery side of the power-related circuit is narrow, and therefore it is possible to provide a wide common ground pattern. However, it is possible to form a common ground pattern to surround the power-related circuit, and to connect the common ground pattern of the upper and lower layers by the through holes. Therefore, noise radiation to the outside can be effectively suppressed.

In the present invention, it is preferable that: the multilayer substrate includes six layers stacked in an order of the first layer, the second layer, the third layer, the fourth layer, a fifth layer, and a sixth layer; the common ground pattern includes a fifth conductive layer provided in the fifth layer and a sixth conductive layer provided in the sixth layer; the fifth layer includes the fifth conductive layer formed over a substrate entire region; the sixth layer includes a sixth layer circuit including the power-related circuit formed therein and the sixth conductive layer formed therein to surround an outer periphery of the sixth layer circuit by an entire periphery of the sixth conductive layer; and the fifth conductive layer and the sixth conductive layer are connected to the second conductive layer, the third conductive layer, and the fourth conductive layer by the through holes. With such a configuration, a space where circuits are to be disposed can be secured in the sixth layer, allowing the power-related circuit to be provided in a wide area. Therefore, a high drive current can be supplied. The common ground pattern is provided over the entire region of the substrate in the fifth layer, and surrounds the sixth layer circuit by the entire periphery of the common ground pattern in the sixth layer, and therefore it is possible to effectively block noise radiation from the power-related circuit to the outside by the ground pattern. Therefore, it is possible to improve the EMC performance while suppressing an increase in costs.

In the present invention, it is preferable that: a plurality of terminal holes into which a plurality of terminals for external connection are fitted are arranged along a substrate outer edge in a first region on one side with respect to a center of the multilayer substrate; the power-related circuit in each of the third layer circuit, the fourth layer circuit, and the sixth layer circuit is disposed in a second region on the side opposite to the first region with respect to the center of the multilayer substrate; in the third layer, the noise guard portion extends along a substrate outer edge of the second region, and both ends of the noise guard portion are connected to portions of the third conductive layer formed in the first region; in the fourth layer, a portion of the fourth conductive layer overlapping with the noise guard portion extends along the substrate outer edge of the second region; in the sixth layer, a portion of the sixth conductive layer overlapping with the noise guard portion extends along the substrate outer edge of the second region; and the plurality of through holes are arranged along the substrate outer edge of the second region. With such a configuration, a common ground pattern can be provided over a wide area in the first region on each layer in which a circuit is formed. In the second region, a space on the outer periphery side of the power-related circuit is narrow, and therefore it is possible to provide a wide common ground pattern. However, it is possible to form a common ground pattern to surround the power-related circuit, and to connect the common ground pattern of the upper and lower layers by the through holes. Therefore, noise radiation to the outside can be effectively suppressed.

In the present invention, it is preferable that: the motor drive circuit includes an electronic element for noise countermeasure, the electronic element for noise countermeasure includes an inductor, and the common ground pattern is formed in a region excluding a region overlapping with the inductor in each layer of the multilayer substrate. With such a configuration, it is possible to prevent stray capacitance from occurring between the inductor and the common ground pattern. Therefore, it is possible to suppress the generation of magnetic lines of force caused by current flowing through the inductor, thus, eddy currents caused by the magnetic lines of force passing through conductors included in the motor drive circuit are suppressed, and as a result, malfunctions and noise in circuit operation caused by eddy currents are suppressed.

In the present invention, it is preferable that: the electronic element for noise countermeasure includes a first capacitor and a second capacitor; and the first capacitor and the second capacitor connect a drive voltage line connected with the inductor in series, to the common ground pattern at two locations on a power supply side and a side of the switching element with respect to the inductor. With such a configuration, the inductor and the two capacitors disposed before and after the inductor function as a T-type low-pass filter, and thus, it is possible to cut high-frequency noise from the power supply side.

In the present invention, it is preferable that: the electronic element for noise countermeasure includes a third capacitor having a smaller capacity than the first capacitor; the first capacitor is disposed on the power supply side with respect to the inductor; and the third capacitor connects the drive voltage line to the common ground pattern on the power supply side with respect to the first capacitor. With such a configuration, on the power supply side with respect to the first capacitor, higher-frequency noise (e.g., MHz-class noise) than noise that can be reduced by the first capacitor (e.g., KHz-class noise) can be reduced first by the third capacitor. Generally, reducing high-frequency noise first will reduce the overall noise level. Therefore, the above arrangement can enhance the noise reduction effect for noise coming from the power supply side.

In the present invention, it is preferable that: the electronic element for noise countermeasure includes a fourth capacitor having a smaller capacity than the second capacitor; the second capacitor is disposed on a side of the switching element with respect to the inductor; and the fourth capacitor connects the drive voltage line to the common ground pattern on a side of the switching element with respect to the second capacitor. With such a configuration, on the side of the switching element with respect to the second capacitor, higher-frequency noise (e.g., MHz-class noise) than noise that can be reduced by the second capacitor (e.g., KHz-class noise) can be reduced first by the fourth capacitor. Generally, reducing high-frequency noise first will reduce the overall noise level. Therefore, the above arrangement can enhance the noise reduction effect for noise coming from the switching element side.

In the present invention, it is preferable that: a fixing portion in which a fixing member to fix the multilayer substrate is disposed and a terminal soldering portion to which a terminal for external connection is soldered are provided in an outer edge of the multilayer substrate; and a through hole for a connector through which a connector pin is inserted and removed is provided between the fixing portion and the terminal soldering portion at the outer edge of the multilayer substrate. Thus, by using the through hole as a hole which the connector pin is inserted into and removed from, the connector can be connected from either the front or back side of the substrate. Therefore, with the multilayer substrate fixed to a motor housing, a connector can be connected to the substrate to write a program and the like. By providing a through hole for the connector between the portion soldered to the terminal and the portion screwed to the housing (i.e., the portion to which the substrate is fixed), deformation of the substrate when the connector is inserted or removed can be suppressed. Therefore, the stress applied to the solder can be reduced, so that the occurrence of solder cracks can be suppressed, and poor electrical continuity can be prevented.

Next, in a case where the motor drive circuit substrate to which the present invention is applied is used for a motor, the motor includes the motor drive circuit substrate and a coil supplied with a drive current output from the motor drive circuit substrate.

Next, in a case where the motor to which the present invention is applied is used for a pump device, the pump device includes an impeller rotationally driven by the motor.

### Effect of the Invention

According to the present invention, a motor drive circuit can be mounted at high density in a multilayer substrate. Since the ground patterns for the signal-related circuit and the power-related circuit are integrated to form a common ground pattern, it is possible to provide a continuous, integrated common ground pattern over a wide area. The common ground pattern is provided over the entire region of the substrate in the second layer of the multilayer substrate, surrounds the third layer circuit by the entire periphery of the common ground pattern in the third layer, and is provided over a wide area surrounding the fourth layer circuit by the entire periphery of the common ground pattern in the fourth layer. Therefore, it is possible to block noise radiation from the circuits provided in the layers to the outside. In particular, in the third layer, the outer periphery of the power-related circuit is surrounded by the common ground pattern (noise guard portion) to prevent any gaps in the circumferential direction, and is connected to the common ground pattern of the upper and lower layers (second and fourth layers) by through holes disposed to surround the power-related circuit, and thus, noise radiation from the power-related circuit is effectively suppressed. Therefore, the motor drive circuit substrate has excellent EMC performance. The effect of suppressing noise radiation is enhanced by the layout of the patterns and through holes on the substrate without adding any parts, and as a result, an increase in costs is suppressed.

### BRIEF DESCRIPTION OF THE DRAWINGS

FIG. 1 is a perspective view of a pump device including a motor to which the present invention is applied.

FIG. 2 is a cross-sectional view of the pump device illustrated in FIG. 1.

FIG. 3 is an exploded perspective view illustrating a state where a cover is removed from the pump device illustrated in FIG. 1.

FIG. 4 is an explanatory diagram of a motor drive circuit mounted on a motor drive circuit substrate according to a first embodiment.

FIG. 5 is a plan view of the motor drive circuit substrate according to the first embodiment.

FIG. 6 is an explanatory diagram of a common ground pattern formed in the motor drive circuit substrate according to the first embodiment.

FIG. 7 illustrates plan views of a first surface and a second surface of a motor drive circuit substrate according to a second embodiment.

FIG. 8 is an explanatory diagram of a motor drive circuit mounted on the motor drive circuit substrate according to the second embodiment.

FIG. 9 is an explanatory diagram of a common ground pattern formed on the motor drive circuit substrate according to the second embodiment.

### MODE FOR CARRYING OUT THE INVENTION

Embodiments of a motor drive circuit substrate, a motor, and a pump device to which the present invention is applied will be described below with reference to the drawings. In the following description, an axial direction means a direction in which a rotation axis L of a motor extends, a radial direction on a radially inner side or a radially outer side means a radial direction centered on the rotation axis L, and a circumferential direction means a rotation direction centered on the rotation axis L. When a direction along the rotation axis L is defined as the axial direction, one side in the axial direction is referred to as L1, and the other side in the axial direction is referred to as L2.

### First Embodiment

### Overall Configuration of Pump Device

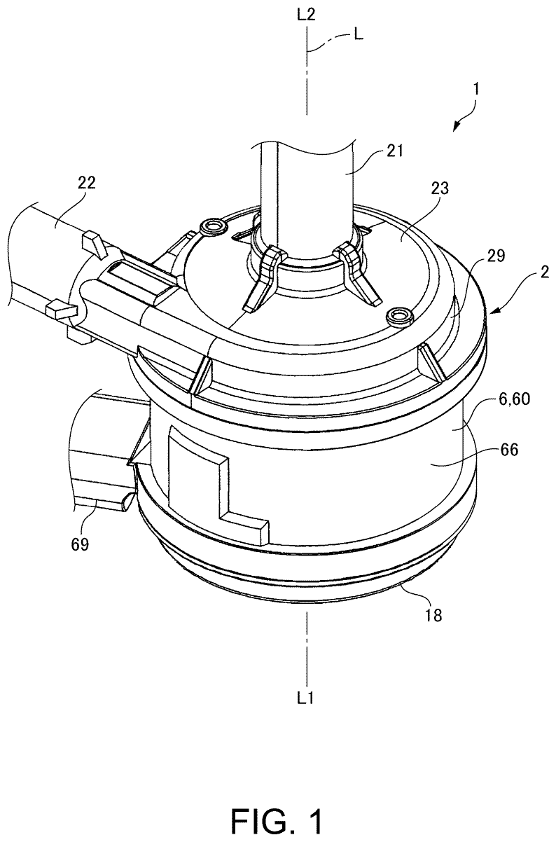

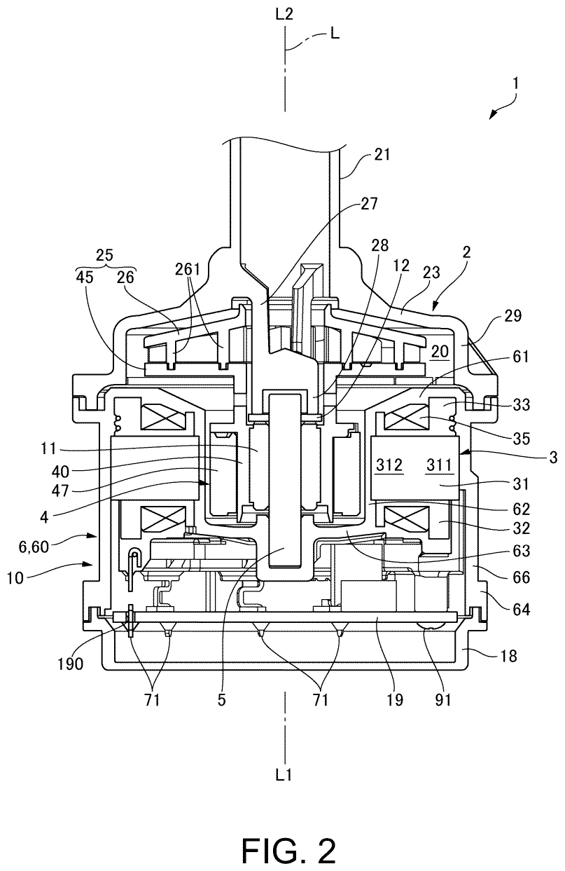

FIG. 1 is a perspective view of a pump device 1 including a motor 10 to which the present invention is applied. FIG. 2 is a cross-sectional view of the pump device 1 illustrated in FIG. 1. In FIGS. 1 and 2, the pump device 1 includes a case 2 including a suction pipe 21 and a discharge pipe 22, a motor 10 disposed on one side L1 in the axial direction with respect to the case 2, and an impeller 25 disposed in a pump chamber 20 inside the case 2. The impeller 25 is driven to rotate about a rotation axis L by the motor 10.

As illustrated in FIG. 2, the pump chamber 20 is provided between the case 2 and a housing 6. The case 2 includes a wall surface 23 of the pump chamber 20 on the other side L2 in the axial direction, and a side wall 29 extending in the circumferential direction. The motor 10 includes a cylindrical stator 3, a rotor 4 disposed inside the stator 3, the housing 6 made of a resin to cover the stator 3, and a support shaft 5 to rotatably support the rotor 4.

In the motor 10, the stator 3 includes a stator core 31, insulators 32 and 33 held by the stator core 31, and a coil 35 wound around the stator core 31 with the insulators 32 and 33 interposed therebetween. The stator core 31 includes an annular portion 311 centered on the rotation axis L, and a plurality of salient poles 312 protruding radially inward from the annular portion 311. The insulators 32 and 33 overlap with the stator core 31 from both sides in the axial direction, and cover each of the plurality of salient poles 312. The coil 35 is wound around the salient poles 312 via the insulators 32 and 33. The motor 10 is a three-phase motor.

The rotor 4 includes a cylindrical portion 40 extending in the axial direction, and a cylindrical magnet 47 is held on an outer peripheral surface of the cylindrical portion 40 to face the stator 3 on the radially inner side. A disk-shaped flange portion 45 is formed at an end portion of the cylindrical portion 40 on the other side L2 in the axial direction, and a disk 26 is coupled to the flange portion 45 from the other side L2 in the axial direction. A plurality of blades 261 are formed at equal angular intervals on a surface of the disk 26 facing the flange portion 45, and the disk 26 is fixed to the flange portion 45 via the blades 261. Therefore, the flange portion 45 and the disk 26 form the impeller 25 connected to the cylindrical portion 40 of the rotor 4.

In the rotor 4, a cylindrical radial bearing 11 is held on the radially inner side of the cylindrical portion 40. The rotor 4 is rotatably supported on the support shaft 5 via the radial bearing 11. An end portion of the support shaft 5 on the one side L1 in the axial direction is non-rotatably held by a bottom wall 63 of the housing 6. The case 2 includes a tubular portion 28 disposed in the radial center of the pump chamber 20 and a support portion 27 to support the tubular portion 28. An end portion of the support shaft 5 on the other side L2 in the axial direction is supported by the tubular portion 28 of the case 2 via a thrust bearing 12.

The housing 6 is a resin sealing member 60 to cover the stator 3 from both sides in the radial direction (i.e., the inner and outer periphery sides) and both sides in the axial direction. Therefore, the housing 6 includes a first partition portion 61 serving as a part of the wall surface of the pump chamber 20, a second partition portion 62 interposed between the stator 3 and the magnet 47, and a cylindrical body portion 66 covering the stator 3 from the radially outer side.

### Motor Drive Circuit Substrate

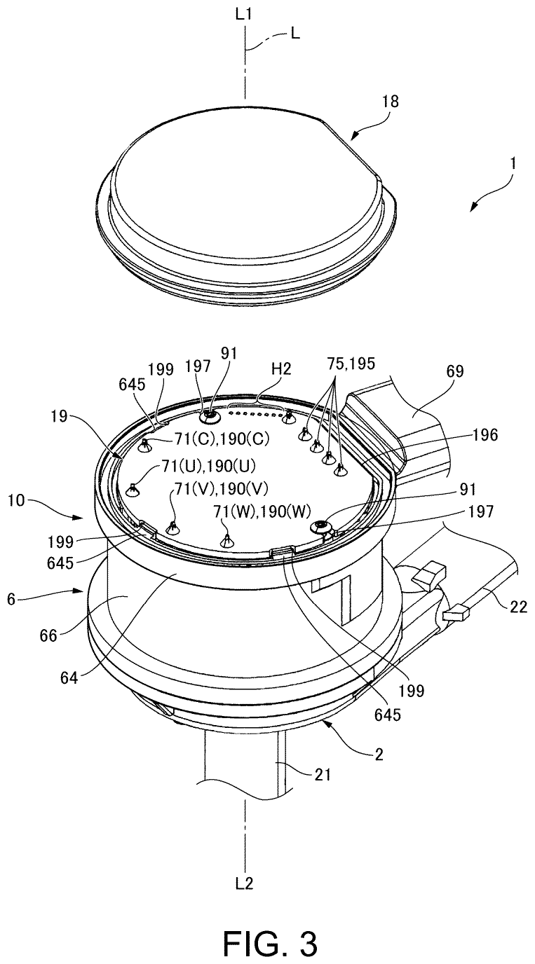

FIG. 3 is an exploded perspective view illustrating the pump device 1 illustrated in FIG. 1 with a cover 18 removed. In FIG. 3, the axial direction is inverted with respect to FIGS. 1 and 2, and the one side L1 in the axial direction is the upper side in the drawing.

As illustrated in FIGS. 2 and 3, the cover 18 is fixed to an end portion 64 of the housing 6 on the one side L1 in the axial direction from the one side L1 in the axial direction. A motor drive circuit substrate 19 is disposed between the cover 18 and the bottom wall 63 of the housing 6. The motor drive circuit substrate 19 includes a circuit to control the power supply to the coil 35. A straight portion 196 cut out in a straight line is provided in an outer peripheral edge of the motor drive circuit substrate 19, and two notches 197 are provided on both sides of the straight portion 196 in the circumferential direction, which serve as fixing portions that fix the circuit substrate to the housing 6. The motor drive circuit substrate 19 is fixed to the housing 6 by screws 91 including tapping screws passing through the two notches 197 (fixing portions). The motor drive circuit substrate 19 is positioned in the circumferential direction by fitting protrusions 645 of the housing 6 into three notches 199 provided on the side opposite to the straight portion 196 in the radial direction.

In the motor drive circuit substrate 19, a plurality of terminal holes 190 into which winding terminals 71 made of a metal are fitted and soldered and which protrude from the stator 3 through the bottom wall 63 of the housing 6 to the one side L1 in the axial direction. The terminal holes 190 are provided in a region on the side opposite to the straight portion 196 in the radial direction in the outer circumferential edge of the motor drive circuit substrate 19. In the first embodiment, a total of four winding terminals 71 protrude from the four terminal holes 190. Of the four winding terminals 71, three winding terminals 71 are connected with one ends of windings included in three coils 35 connected in series. The remaining winding terminal 71 is a common (C) terminal, to which the other ends of the windings are electrically connected.

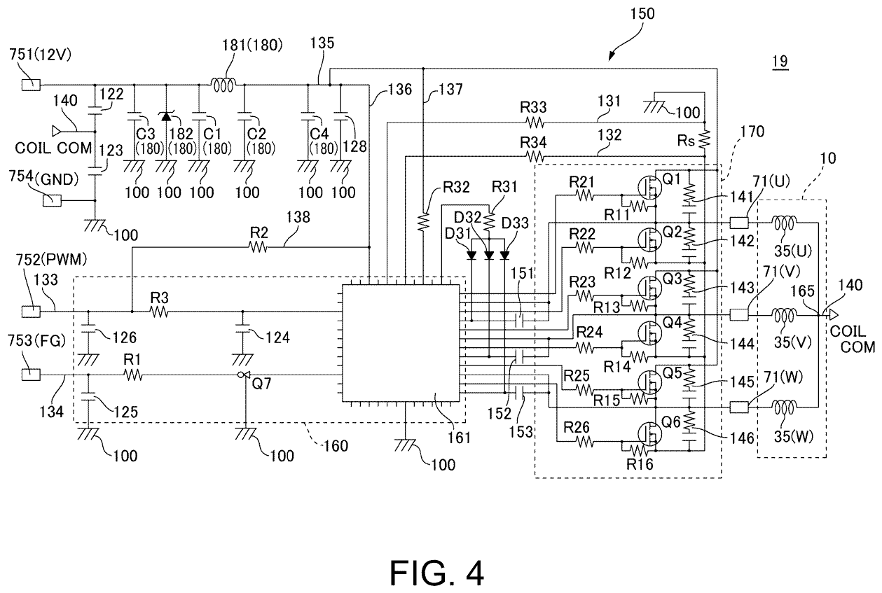

In the motor drive circuit substrate 19, a plurality of terminal holes 195 into which connector terminals 75 made of a metal are fitted and soldered are provided, and the connector terminals 75 are held by the housing 6. The terminal holes 195 are aligned in a row along the straight portion 196 of the motor drive circuit substrate 19. In the motor drive circuit substrate 19, wires and the like to electrically connect a motor drive circuit 150 (see FIG. 4) to the winding terminals 71 and the connector terminals 75 are formed.

A cylindrical connector housing 69 that protrudes toward the outer periphery side is formed in the housing 6, and ends of the connector terminals 75 are located inside the connector housing 69. Therefore, when a connector is coupled to the connector housing 69 and signals or the like are supplied, the signals are input to the motor drive circuit 150 via the connector terminals 75, and a drive current generated in the motor drive circuit 150 is supplied to each coil 35 via the corresponding winding terminal 71. As a result, the rotor 4 rotates around the rotation axis L. Thus, the impeller 25 rotates within the pump chamber 20 and the inside of the pump chamber 20 becomes negative pressure, so that a fluid is sucked into the pump chamber 20 from the suction pipe 21 and discharged from the discharge pipe 22.

### Motor Drive Circuit

FIG. 4 is an explanatory diagram of the motor drive circuit 150 mounted on the motor drive circuit substrate 19 according to the first embodiment. FIG. 4 illustrates a schematic configuration of the motor drive circuit 150. As mentioned above, the motor 10 is a three-phase motor. In the following description, the three-phase coil 35 may be described with the letters U, V, and W indicating their respective phases, but when it is not necessary to identify the phase, it will be described as the coil 35 without the letters U, V, and W indicating their respective phases.

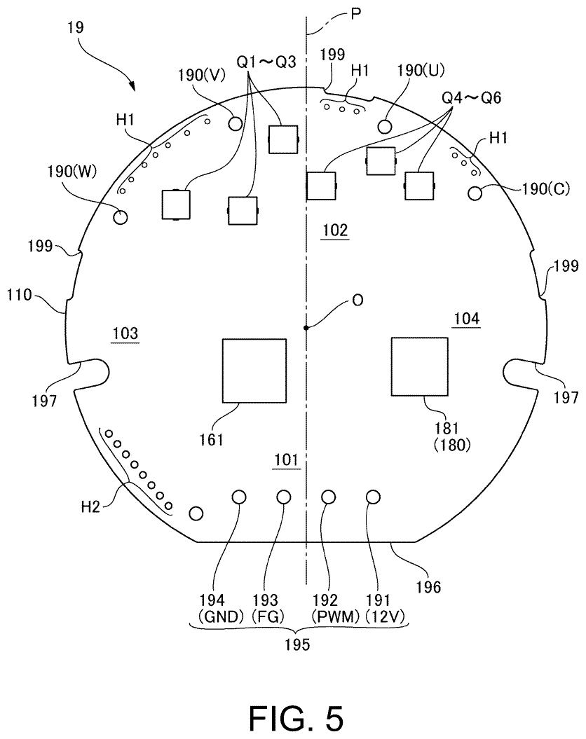

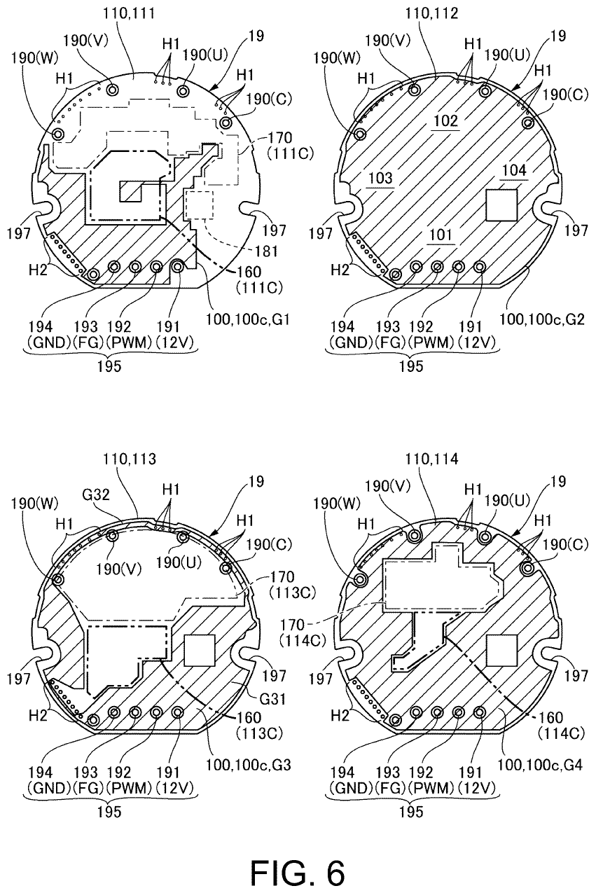

The motor drive circuit substrate 19 is one in which the motor drive circuit 150 illustrated in FIG. 4 is mounted in a multilayer substrate 110 (see FIGS. 5 and 6). As illustrated in FIG. 4, the motor drive circuit 150 includes a signal-related circuit 160 including a motor control unit 161 that controls the rotation of the motor 10 by a PWM signal, a power-related circuit 170 including an inverter that supplies a drive current to the three-phase coil 35, based on an output signal from the motor control unit 161, a drive voltage line 135 that supplies a drive voltage to the power-related circuit 170, and a common line 140 connected to a neutral point 165 of three-phase coils 35U, 35V, and 35W. The drive voltage line 135 supplies a rated voltage of 12 V to the motor control unit 161 and the power-related circuit 170.

The motor drive circuit 150 also includes a control signal line 133 used for inputting a PWM signal from an external device to the motor control unit 161, and an FG output line 134 used for transmitting a rotation speed signal corresponding to the rotation speed of the motor 10 to the external device.

The motor drive circuit substrate 19 includes the four connector terminals 75 including a constant voltage terminal 751, a first signal terminal 752, a second signal terminal 753, and a ground terminal 754, which will be described below. The constant voltage terminal 751 is electrically connected to the drive voltage line 135, the first signal terminal 752 is electrically connected to the control signal line 133, and the second signal terminal 753 is electrically connected to the FG output line 134. The ground terminal 754 is electrically connected to a ground pattern 100 of the motor drive circuit substrate 19.

The drive voltage line 135 branches into a first line 136 and a second line 137 to supply electric power to the motor control unit 161 via the first line 136 and the second line 137. The second line 137 is electrically connected to the motor control unit 161 via a resistor R32. Capacitors 122 and 123 are electrically connected in series between the drive voltage line 135 and the ground pattern 100. The common line 140 is electrically connected to a point between the capacitors 122 and 123. The ground terminal 754 to which a ground potential is applied is electrically connected to a point between the capacitor 123 and the ground pattern 100.

The motor drive circuit 150 includes a plurality of electronic elements for noise countermeasure 180 electrically connected to the drive voltage line 135 downstream of the capacitors 122 and 123. The electronic elements for noise countermeasure 180 according to the first embodiment include an inductor 181 connected in series to the drive voltage line 135, a diode 182 electrically connected between the drive voltage line 135 and the ground pattern 100 upstream of the inductor 181, and a plurality of capacitors electrically connected between the drive voltage line 135 and the ground pattern 100 upstream and downstream of the inductor 181. In the first embodiment, the capacitors include four capacitors including a first capacitor C1, a second capacitor C2, a third capacitor C3, and a fourth capacitor C4, which are electrolytic capacitors. The diode 182 protects the elements in the motor drive circuit 150 from surge voltages.

The electronic elements for noise countermeasure 180 are not limited to the above-listed elements, and other elements may be used. For example, ferrite beads may be used. The number and arrangement of the capacitors may also be varied.

The inductor 181 is, for example, a choke coil. The first capacitor C1 is disposed immediately before the inductor 181. The second capacitor C2 is disposed immediately after the inductor 181. The three elements including the inductor 181, the first capacitor C1, and the second capacitor C2 function as a T-type low-pass filter. The diode 182 is disposed upstream of the first capacitor C1, and the third capacitor C3 is disposed upstream of the diode 182. The third capacitor C3 has a smaller capacitance than the first capacitor C1. The fourth capacitor C4 is disposed downstream of the second capacitor C2. The fourth capacitor C4 has a smaller capacitance than the second capacitor C2. Downstream of the fourth capacitor C4, a capacitor 128 which is an electrolytic capacitor is electrically connected between the first line 136 and the ground pattern 100.

The control signal line 133 transmits a PWM signal from the external device to the motor control unit 161. A resistor R3 is electrically connected in series to the control signal line 133. A point of the control signal line 133 between the resistor R3 and the motor control unit 161 is electrically connected to the ground pattern 100 via a capacitor 124. A point of the control signal line 133 between the first signal terminal 752 and the resistor R3 may be electrically connected to the ground pattern 100 via a capacitor 126. In this case, a connection point between the capacitor 126 and the resistor R3 is electrically connected to the first line 136 via a third line 138. A resistor R2 is electrically connected in series to the third line 138.

The FG output line 134 transmits the rotation speed signal of the motor 10 output from the motor control unit 161 to the external device. The FG output line 134 is connected with a capacitor 125, a resistor R1, and a NOT gate Q7. The capacitor 125 is electrically connected between the FG output line 134 and the ground pattern 100. The resistor R1 is electrically connected in series to the FG output line 134 between the connection point of the capacitor 125 and the motor control unit 161. The NOT gate Q7 is electrically connected in series to the FG output line 134 between the resistor R1 and the motor control unit 161.

The motor control unit 161 includes a control element such as an IC chip mounted on the motor drive circuit substrate 19. The motor control unit 161 outputs an output signal to control the power-related circuit 170 based on the PWM signal input from the external device. The motor control unit 161 also outputs a rotation speed signal corresponding to the rotation speed of the rotor 4 to the external device. The external device outputs the PWM signal to the motor control unit 161 to rotate the motor 10 at a desired rotation speed, based on the rotation speed signal.

The power-related circuit 170 includes switching elements Q1 and Q2 for the U-phase coil, switching elements Q3 and Q4 for the V-phase coil, and switching elements Q5 and Q6 for the W-phase coil. The switching elements Q1 to Q6 are, for example, MOS-type FETs. The drains of the switching elements Q1, Q3, and Q5 are connected to the drive voltage line 135, and the sources of the switching elements Q2, Q4, and Q6 are connected to the ground pattern 100 via a shunt resistor Rs. Both ends of the shunt resistor Rs are connected to the motor control unit 161 via output lines 131 and 132. Resistors R33 and R34 are electrically connected in series to the Output lines 131 and 132.

A capacitor 151 is connected to the source of the switching element Q1 and the drain of the switching element Q2, a capacitor 152 is connected to the source of the switching element Q3 and the drain of the switching element Q4, and a capacitor 153 is connected to the source of the switching element Q5 and the drain of the switching element Q6. The capacitors 151 to 153 serve as charge/discharge capacitors for bootstrap circuits. Diodes D31 to D33 for bootstrap are connected between the capacitors 151 to 153 and the motor control unit 161, respectively. The diodes D31 to D33 are connected to the motor control unit 161 via a resistor R31.

Resistors R11 to R16 are connected between the gates and sources of the switching elements Q1 to Q6, respectively. Resistors R21 to R26 are connected between the gates of the switching elements Q1 to Q6 and the motor control unit 161, respectively. Filters 141 to 146 are connected between the drains and sources of the switching elements Q1 to Q6, respectively. The filters 141 to 146 each include a resistor and a capacitor, which are connected in series.

In the power-related circuit 170, the switching elements Q1 to Q6 are switched on and off based on the output signal outputted from the motor control unit 161 to supply a three-phase AC drive current to the coil 35.

### Multilayer Substrate

FIG. 5 is a plan view of the motor drive circuit substrate 19 according to the first embodiment. FIG. 6 is an explanatory diagram of a common ground pattern 100c formed in the motor drive circuit substrate 19 according to the first embodiment. The motor drive circuit substrate 19 is the multilayer substrate 110 having a plurality of layers. In the multilayer substrate 110, a plurality of insulating layers are laminated on a substrate body to form a plurality of layers in which conductive layers such as wires and electrodes are disposed, and the conductive layers formed in different layers are electrically connected to each other by contact holes that penetrate the insulating layers. The conductive layers such as wires and electrodes are formed of copper layers.

As illustrated in FIG. 5, in a first region 101 on one side with respect to a center O of the multilayer substrate 110, the plurality of terminal holes 195 into which the connector terminals 75 are fitted are provided. The plurality of terminal holes 195 are arranged in a row along the straight portion 196 on the substrate outer edge. The plurality of terminal holes 195 include a first terminal hole 191, a second terminal hole 192, a third terminal hole 193, and a fourth terminal hole 194, into which the constant voltage terminal 751, the first signal terminal 752, the second signal terminal 753, and the ground terminal 754 illustrated in FIG. 4 out of the connector terminals 75 fit respectively. Therefore, of the plurality of terminal holes 195, the two located at both ends (the first terminal hole 191 and the fourth terminal hole 194) correspond to a constant voltage. The wires extending from the first terminal hole 191 and the fourth terminal hole 194 corresponding to the constant voltage can be used as shield wires.

As illustrated in FIG. 5, in a second region 102 on the side opposite to the first region 101 with respect to the center O of the multilayer substrate 110, the switching elements Q1 to Q6 are mounted. When two regions located on both sides in a direction intersecting a virtual line P extending linearly through the first region 101, the center O, and the second region 102 are defined as a third region 103 and a fourth region 104, the motor control unit 161 is disposed on the side of the third region 103 with respect to the center O. Also in the fourth region 104, the inductor 181 is disposed. The inductor 181 being disposed near the terminal hole 195 (the first terminal hole 191 or the fourth terminal hole 194) corresponding to the constant voltage can particularly improve the EMC performance.

Here, when the circuit including the motor control unit 161 is referred to as the signal-related circuit 160 with relatively low voltages and the circuit including the switching elements Q1 to Q6 that output a drive current is referred to as the power-related circuit 170 with relatively high voltages as illustrated in FIG. 4, the ground pattern 100 includes the common ground pattern 100c, which is electrically connected to both the signal-related circuit 160 and the power-related circuit 170, as illustrated in FIG. 6. The common ground pattern 100c functions both as the ground pattern 100 for the signal-related circuit 160 and as the ground pattern 100 for the power-related circuit 170.

The multilayer substrate 110 includes four layers including a first layer 111, a second layer 112, a third layer 113, and a fourth layer 114, as illustrated in FIG. 6. Of the four layers of the multilayer substrate 110, the first layer 111 that is the uppermost layer is formed with lands (not illustrated) on which electrical elements included in the motor drive circuit 150 illustrated in FIG. 4 are mounted. The first layer 111, the second layer 112, the third layer 113, and the fourth layer 114 each have a conductive layer formed therein that functions as the common ground pattern 100c. The common ground pattern 100c includes a first conductive layer G1 formed in the first layer 111, a second conductive layer G2 formed in the second layer 112, a third conductive layer G3 formed in the third layer 113, and a fourth conductive layer G4 formed in the fourth layer 114. In FIG. 6, regions where these conductive layers are formed are represented as hatched regions.

The motor drive circuit 150 illustrated in FIG. 4 includes a first layer circuit 111C provided in the first layer 111, a third layer circuit 113C provided in the third layer, and a fourth layer circuit 114C provided in the fourth layer, as illustrated in FIG. 6. Here, the shapes of the circuits and conductive layers in the layers illustrated in FIG. 6 represent regions in which the electrical elements, wires, conductive layers, and the like included in the circuits are approximately disposed, but fine wires, contact holes, and the like are not illustrated. For example, the region in which a wire extending from the first layer circuit 111C to the terminal hole 195 on the substrate outer edge is disposed is not illustrated. The conductive layers are not formed around the contact holes or around the wires.

The first layer circuit 111C, the third layer circuit 113C, and the fourth layer circuit 114C each include a part of the signal-related circuit 160 and a part of the power-related circuit 170. As illustrated in FIG. 6, the first layer circuit 111C includes the signal-related circuit 160 disposed centered on a central region of the substrate, and the power-related circuit 170 being disposed in a region centered on the second region 102 and extending to the third region 103 and the fourth region 104. The first conductive layer G1 is formed centered on the first region 101 and extends to the third region 103 and a part of the fourth region 104.

In the second layer 112, the second conductive layer G2 is formed over the entire region of the substrate, and the second conductive layer G2 also extends to the substrate outer edge. In the third layer 113, the third conductive layer G3 is formed to surround the outer periphery of the third layer circuit 113C by the entire periphery of the third conductive layer G3. Also in the fourth layer 114, the fourth conductive layer G4 is formed to surround the outer periphery of the fourth layer circuit 114C by the entire periphery of the fourth conductive layer G4.

As illustrated in FIG. 6, the third layer circuit 113C includes the signal-related circuit 160 disposed in a central region of the substrate, and the power-related circuit 170 disposed in a region being centered on the second region 102 and extending to the third region 103 and the fourth region 104. The power-related circuit 170 extends close to the substrate outer edge, and extends to the positions of the four terminal holes 190 to which the winding terminals 71 are soldered. The third conductive layer G3 includes a third conductive layer main body G31 formed to surround the third layer circuit 113C from the first region 101, third region 103, and fourth region 104 sides, and a noise guard portion G32 extending along the substrate outer edge of the second region 102 to surround the outer periphery of the power-related circuit 170. The noise guard portion G32 extends in an arc shape, and both ends in the circumferential direction extend to the third region 103 and the fourth region 104 and are connected to the third conductive layer main body G31.

The fourth layer circuit 114C includes the signal-related circuit 160 disposed in a central region of the substrate, and the power-related circuit 170 disposed in the second region 102. The region in which the fourth layer circuit 114C is disposed is smaller overall than the region in which the third layer circuit 113C is disposed. The fourth conductive layer G4 includes a portion extending along the substrate outer edge of the second region 102 and overlapping with the noise guard portion G32 of the third conductive layer G3.

It should be noted that either or both of the third layer circuit 113C and the fourth layer circuit 114C may be configured to include the power-related circuit 170 without including the signal-related circuit 160.

The common ground pattern 100c is not formed in any portion of each layer of the multilayer substrate 110 that overlaps with the inductor 181 mounted in the first layer 111. As illustrated in FIG. 6, each of the second conductive layer G2, the third conductive layer G3, and the fourth conductive layer G4 has a hollowed-out shape where each layer overlaps with the inductor 181.

As illustrated in FIGS. 5 and 6, a plurality of through holes H1 arranged along the substrate outer edge of the second region 102 are provided in the multilayer substrate 110. Also in the multilayer substrate 110, a plurality of through holes for a connector H2 arranged along the substrate outer edge are provided between the notches 197 (fixing portions for the housing 6) disposed in the third region 103 and the terminal holes 195. The through holes H1 provided on the substrate outer edge of the second region 102 are disposed to surround the outer periphery of the power-related circuit 170 of the third layer circuit 113C. The through holes H1 are formed in the region of the noise guard portion G32 of the third conductive layer G3. The noise guard portion G32 is electrically connected to the second conductive layer G2 and the fourth conductive layer G4 by the through holes H1.

In the first embodiment, most of the power-related circuit 170 is consolidated in a layer (the third layer 113) between two layers (the second layer 112 and the fourth layer 114) in which the common ground pattern 100c is provided over a wide area. Thus, in the third layer circuit 113C, the region in which the power-related circuit 170 is disposed is extended close to the substrate outer edge to ensure the area where the power-related circuit 170 is disposed. As a result, the space where the noise guard portion G32 is to be formed is narrowed. The noise guard portion G32 has a pattern width of about 0.5 mm at its narrowest portion. The inner diameter of each through hole H1 disposed in the noise guard portion G32 is about 0.3 mm, and therefore the pattern width of the noise guard portion G32 is larger than the inner diameter of the through hole H1. Even though the noise guard portion G32 is thin, the noise guard portion G32 continuously surrounds the outer periphery of the power-related circuit 170 in the third layer 113 and connect the common ground pattern 100c of the upper and lower layers (the second conductive layer G2 and the fourth conductive layer G4) by the through holes H1 to reduce noise radiation from the power-related circuit 170 consolidated in the third layer 113 to the outside of the substrate.

### Main Advantageous Effects of First Embodiment

As described above, the pump device 1 according to the first embodiment includes the motor 10 and the impeller 25 rotationally driven by the motor 10. The motor 10 includes the motor drive circuit substrate 19 in the multilayer substrate 110 in which the motor drive circuit 150 is provided including: the power-related circuit 170 including the switching elements Q1 to Q6 that output a drive current; and the signal-related circuit 160 including the motor control unit 161 (a control element) that supplies a control signal to the switching elements Q1 to Q6. In the multilayer substrate 110, the ground pattern 100 for the power-related circuit 170 and the ground pattern 100 for the signal-related circuit 160 are configured as the integrated common ground pattern 100c. The multilayer substrate 110 includes the four layers including the first layer 111, the second layer 112, the third layer 113, and the fourth layer 114, which are stacked in this order. The common ground pattern 100c includes the second conductive layer G2 provided in the second layer 112, the third conductive layer G3 provided in the third layer 113, and the fourth conductive layer G4 provided in the fourth layer 114. In the first layer 111, the motor control unit 161 and the switching elements Q1 to Q6 are mounted. In the second layer 112, the second conductive layer G2 is formed over the entire region of the substrate. In the third layer 113, the third layer circuit 113C including the power-related circuit 170 is formed and the third conductive layer G3 is formed to surround the outer periphery of the third layer circuit 113C by the entire periphery of the third conductive layer G3. In the fourth layer 114, the fourth layer circuit 114C including the power-related circuit 170 is formed and the fourth conductive layer G4 is formed to surround the outer periphery of the fourth layer circuit 114C by the entire periphery of the fourth conductive layer G4. The third conductive layer G3 includes the noise guard portion G32 extending along the outer periphery of the power-related circuit 170. The noise guard portion G32 is connected to the second conductive layer G2 and the fourth conductive layer G4 by the plurality of through holes H1 arranged to surround the power-related circuit 170.

In the first embodiment, since the multilayer substrate 110 is used as the motor drive circuit substrate 19, the motor drive circuit 150 can be mounted at high density. In addition, the common ground pattern 100c can be provided continuously and integrally over a wide area. The common ground pattern 100c is provided over the entire region of the second layer 112 of the multilayer substrate 110, surrounds the third layer circuit 113C by the entire periphery of the common ground pattern 100c in the third layer 113, and is also provided over a wide area surrounding the fourth layer circuit 114C by the entire periphery of the common ground pattern 100c in the fourth layer 114. Therefore, it is possible to block noise radiation from the power-related circuit 170 provided in the layers to the outside. In particular, in the third layer 113, the outer periphery of the power-related circuit 170 is surrounded by the noise guard portion G32 so that no gaps are formed in the circumferential direction, and the common ground pattern 100c of the upper and lower layers (the second layer 112 and the fourth layer 114) are connected to each other by the through holes H1 disposed to surround the power-related circuit 170, to effectively suppress noise radiation from the power-related circuit 170. Therefore, the motor drive circuit substrate 19 has excellent EMC performance. The effect of suppressing noise radiation is enhanced by the layout of the patterns and the through holes H1 on the substrate without adding any parts, and as a result, an increase in costs is suppressed.

In the first embodiment, the plurality of terminal holes 195 are arranged along the substrate outer edge in the first region 101 on one side with respect to the center of the multilayer substrate 110. The power-related circuit 170 in the third layer 113 is disposed in the second region 102 on the side opposite to the first region 101 with respect to the center of the multilayer substrate 110. The noise guard portion G32 extends along the substrate outer edge in the second region 102, and both ends of the noise guard portion G32 are connected to portions of the third conductive layer G3 formed in the first region 101 (the third conductive layer main body G31). The plurality of through holes H1 are arranged along the substrate outer edge of the second region 102.

With such a pattern arrangement, in the first embodiment, the common ground pattern 100c (the third conductive layer main body G31) can be provided over a wide area in the first region 101 of the third layer 113, and the power-related circuit 170 can be provided over a wide area in the second region 102. In the case where the power-related circuit 170 is provided over a wide area in the second region 102 (e.g., in the case where the power-related circuit 170 is consolidated in the third layer 113), the space on the outer periphery side of the power-related circuit 170 becomes narrow, so that the noise guard portion G32 cannot be made wide. However, in the first embodiment, the noise guard portion G32 is formed to surround the power-related circuit 170 by the entire periphery of the noise guard portion G32, and the common ground pattern 100c of the upper and lower layers are connected to each other by the through holes H1, to suppress noise radiation to the outside.

In the first embodiment, the motor drive circuit 150 includes the electronic elements for noise countermeasure 180 in addition to the common ground pattern 100c, and therefore has excellent EMC performance. The electronic elements for noise countermeasure 180 include the inductor 181, and the common ground pattern 100c is formed in a region excluding the region overlapping with the inductor 181 on each layer of the multilayer substrate 110. By arranging the patterns so that the inductor 181 and the common ground pattern 100c do not face each other in this manner, it is possible to prevent stray capacitance from occurring between the inductor 181 and the common ground pattern 100c. Therefore, it is possible to suppress the generation of magnetic lines of force caused by current flowing through the inductor 181, and thus, eddy currents caused by the magnetic lines of force passing through conductors included in the motor drive circuit 150 can be suppressed to suppress malfunctions and noise in circuit operation caused by eddy currents.

In the first embodiment, the electronic elements for noise countermeasure 180 include the first capacitor C1 and the second capacitor C2. The first capacitor C1 and the second capacitor C2 connect the drive voltage line 135, to which the inductor 181 is connected in series, to the common ground pattern 100c at two points: on the power supply side and on the switching elements Q1 to Q6 side with respect to the inductor 181. Thus, the inductor 181 and the two capacitors disposed before and after the inductor 181 function as a T-type low-pass filter, making it possible to cut high-frequency noise from the power supply side.

In the first embodiment, the electronic elements for noise countermeasure 180 include the third capacitor C3 having a smaller capacitance than the first capacitor C1. The first capacitor C1 is disposed on the power supply side with respect to the inductor 181, and the third capacitor C3 connects the drive voltage line 135 to the common ground pattern 100c on the power supply side with respect to the first capacitor C1. In other words, the capacitances of the capacitors connected to the drive voltage line 135 are arranged in ascending order from the power supply side toward the inductor 181 side. Thus, on the power supply side with respect to the first capacitor C1, higher-frequency noise (e.g., MHz-class noise) than noise that can be reduced by the first capacitor C1 (e.g., KHz-class noise) can be reduced first by the third capacitor C3. Generally, reducing frequency noise first will reduce the overall noise level. Therefore, the above arrangement order can enhance the noise reduction effect for noise coming from the power supply side.

In the first embodiment, the electronic elements for noise countermeasure 180 include the fourth capacitor C4 having a smaller capacitance than the second capacitor C2. The second capacitor C2 is disposed on the switching elements Q1 to Q6 side with respect to the inductor 181, and the fourth capacitor C4 connects the drive voltage line 135 to the common ground pattern 100c on the switching elements Q1 to Q6 side with respect to the second capacitor C2. In other words, the capacitances of the capacitors connected to the drive voltage line 135 are arranged in ascending order from the switching element side toward the inductor 181 side. Thus, on the switching elements Q1 to Q6 side with respect to the second capacitor C2, higher-frequency noise (e.g., MHz-class noise) than noise that can be reduced by the second capacitor C2 (e.g., KHz-class noise) can be reduced first by the fourth capacitor C4. Generally, reducing high-frequency noise first will reduce the overall noise level. Therefore, the above arrangement can enhance the noise reduction effect for noise coming from the switching elements Q1 to Q6 side.

In the first embodiment, the notches 197, which are fixing portions in which fixing members (e.g., screws) to fix the multilayer substrate 110 are disposed, and the terminal holes 195, which are terminal soldering portions in which terminals for external connection are soldered, are provided in the outer edge of the multilayer substrate 110. The through holes for a connector H2 where connector pins are inserted into and removed from are provided between the notches 197, which are screw fixing portions, and the terminal soldering portions (the terminal holes 195) in the outer edge of the multilayer substrate 110. Thus, by using the through holes H1 as holes for inserting and removing connector pins, a connector can be connected from either the front or back side of the multilayer substrate 110 Therefore, with the motor drive circuit substrate 19 (the multilayer substrate 110) fixed to the housing 6 of the motor 10 as illustrated in FIG. 3, a connector can be connected to the through holes for a connector H2 to write a program and the like, without removing the motor drive circuit substrate 19 from the housing 6. By the through holes for a connector H2 being provided between the terminal soldering portions (the terminal holes 195) and the screw fixing portions (the notches 197) of the motor drive circuit substrate 19, the stress applied to the motor drive circuit substrate 19 when the connector is inserted or removed can be reduced. Therefore, the occurrence of solder cracks due to the stress can be suppressed, and poor electrical continuity can be prevented. The fixing portions that fix the motor drive circuit substrate 19 to the housing 6 may be through holes instead of having a notch shape. The fixing member may be a member other than a screw. For example, a hook or crimping portion formed integrally with the housing may be used.

### Second Embodiment

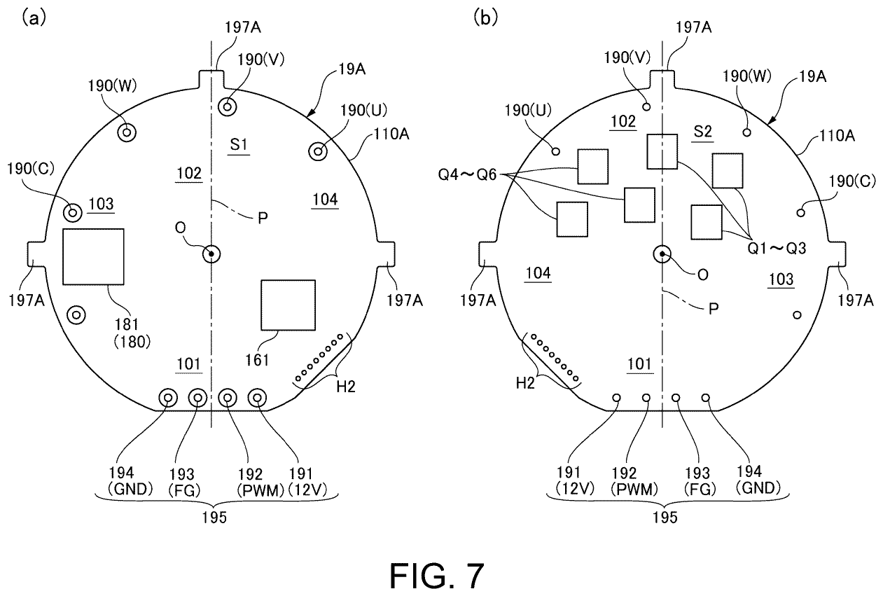

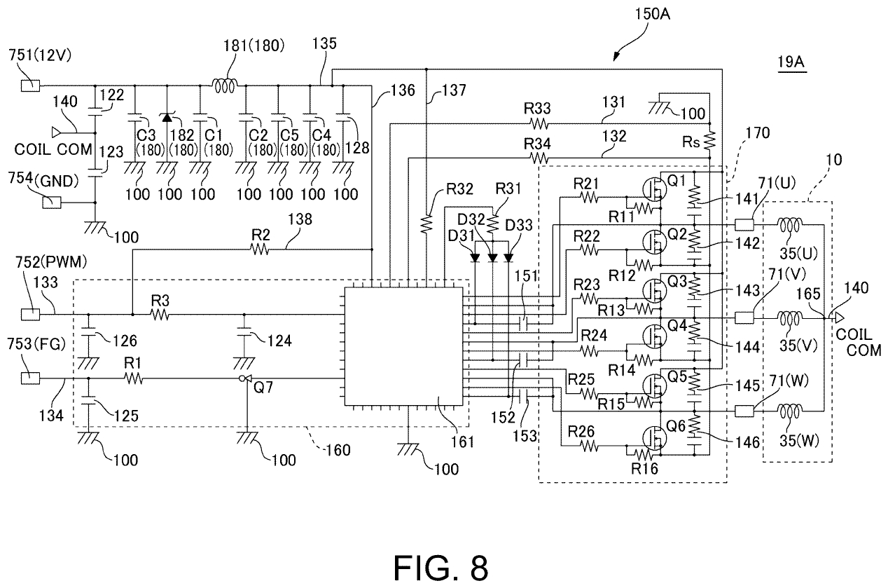

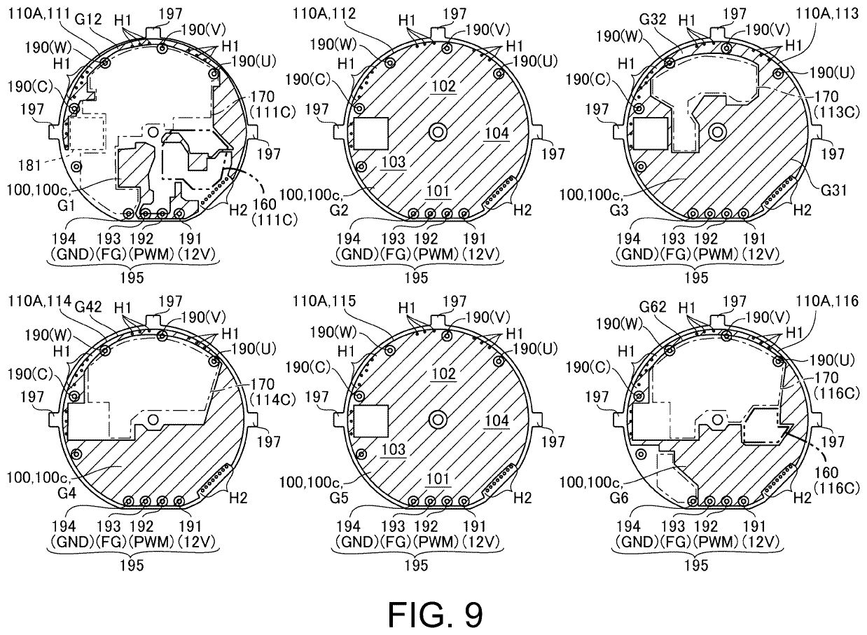

FIG. 7 illustrates plan views of a first surface S1 and a second surface S2 of a motor drive circuit substrate 19A according to a second embodiment. FIG. 8 is an explanatory diagram of a motor drive circuit 150 mounted on the motor drive circuit substrate 19A according to the second embodiment. FIG. 9 is an explanatory diagram of the common ground pattern 100c formed in the motor drive circuit substrate 19A according to the second embodiment. Since the basic configuration of the second embodiment is similar to that of the first embodiment, the same reference numerals are used for the common parts and the description thereof will be omitted.

The motor drive circuit substrate 19 according to the first embodiment is a multilayer single-sided substrate, whereas the motor drive circuit substrate 19A according to the second embodiment is a double-sided mounting substrate. As illustrated in (a) of FIG. 7, the inductor 181 is mounted on the third region 103 side of the first surface S1 of the motor drive circuit substrate 19A, and the motor control unit 161 is mounted at a position on the first region 101 side and the fourth region 104 side with respect to the center O. As illustrated in (b) of FIG. 7, the switching elements Q1 to Q6 are mounted in the second region 102 on the second surface S2 opposite to the first surface S1 of the motor drive circuit substrate 19A.

As illustrated in FIG. 8, a motor drive circuit 150A according to the second embodiment differs from the first embodiment in that, in addition to the first capacitor C1 to the fourth capacitor C4, a fifth capacitor C5, which is an electrolytic capacitor, is provided as an electronic element for noise countermeasure 180. The fifth capacitor C5 is disposed between the second capacitor C2 and the fourth capacitor C4. The second capacitor C2, the fifth capacitor C5, and the fourth capacitor C4 are arranged in ascending order of capacitance from the switching element side toward the inductor 181 side.

As illustrated in FIG. 9, the motor drive circuit substrate 19A is a multilayer substrate 110A, and includes six layers including a first layer 111, a second layer 112, a third layer 113, a fourth layer 114, a fifth layer 115, and a sixth layer 116, which are stacked in this order. A conductive layer serving as the common ground pattern 100c is formed in each layer. The common ground pattern 100c includes a first conductive layer G1 formed in the first layer 111, a second conductive layer G2 formed in the second layer 112, a third conductive layer G3 formed in the third layer 113, a fourth conductive layer G4 formed in the fourth layer 114, a fifth conductive layer G5 formed in the fifth layer 115, and a sixth conductive layer G6 formed in the sixth layer 116. In FIG. 9, regions where these conductive layers are formed are represented as hatched regions.

The motor drive circuit 150A includes a first layer circuit 111C provided in the first layer 111, a third layer circuit 113C provided in the third layer, a fourth layer circuit 114C provided in the fourth layer, and a sixth layer circuit 116C formed in the sixth layer.

In the second embodiment, the first layer circuit 111C and the sixth layer circuit 116C include a part of the signal-related circuit 160 and a part of the power-related circuit 170, respectively. On the other hand, the third layer circuit 113C and the fourth layer circuit 114C do not include the signal-related circuit 160 but include a part of the power-related circuit 170. The power-related circuit 170 is disposed mainly in the second region 102 in each layer.

The common ground pattern 100c is not formed in a portion overlapping with the inductor 181 mounted in the first layer 111, as in the first embodiment. As illustrated in FIG. 9, each of the second conductive layer G2, the third conductive layer G3, the fourth conductive layer G4, the fifth conductive layer G5, and the sixth conductive layer G6 has a out shape where each layer overlaps with the inductor 181.

As illustrated in FIG. 9, the first conductive layer G1 is formed along the substrate outer edges of the first region 101, the fourth region 104, and the second region 102. The portion of the second region 102 extending along the substrate outer edge is a noise guard portion G12 surrounding the outer periphery of the power-related circuit 170. In the second layer 112 and the fifth layer 115, the second conductive layer G2 and the fifth conductive layer G5 are formed over the entire region of the substrate, respectively.

In the third layer 113 and the fourth layer 114, the third conductive layer G3 and the fourth conductive layer G4 are formed to surround the outer periphery of the power-related circuit 170 included in the third layer circuit 113C and the fourth layer circuit 114C, by the entire peripheries of the third conductive layer G3 and the fourth conductive layer G4, respectively. The third conductive layer G3 includes a third conductive layer main body G31 disposed on the first region 101, third region 103, and fourth region 104 sides with respect to the power-related circuit 170, and the noise guard portion G32 extending along the substrate outer edge of the second region 102 to surround the outer periphery of the power-related circuit 170. The fourth conductive layer G4 includes a noise guard portion G42 overlapping with the noise guard portion G32 of the third conductive layer G3. The noise guard portion G42 extends along the substrate outer edge of the second region 102 in the fourth layer 114 to surround the outer periphery of the power-related circuit 170.

In the multilayer substrate 110A according to the second embodiment, the plurality of through holes H1 arranged along the substrate outer edge of the second region 102 are provided. The noise guard portion G32 of the third layer 113 and the noise guard portion G42 of the fourth layer 114 are electrically connected to each other by the through holes H1. The noise guard portion G32 is electrically connected to the second conductive layer G2 by the through holes H1, and the noise guard portion G42 is electrically connected to the fifth conductive layer G5. In the multilayer substrate 110A according to the second embodiment, the through holes H1 penetrate the regions in which the common ground pattern 100c is formed in the first layer 111, the second layer 112, the third layer 113, the fourth layer 114, the fifth layer 115, and the sixth layer 116.

### Main Advantageous Effects of Second Embodiment

As described above, in the second embodiment, the multilayer substrate 110A includes six layers including the first layer 111, the second layer 112, the third layer 113, the fourth layer 114, the fifth layer 115, and the sixth layer 116, which are stacked in this order. The common ground pattern 100c includes the first conductive layer G1, the second conductive layer G2, the third conductive layer G3, and the fourth conductive layer, as in the first embodiment, and further includes the fifth conductive layer G5 provided in the fifth layer 115, and the sixth conductive layer G6 provided in the sixth layer 116. In the fifth layer 115, the fifth conductive layer G5 is formed over the entire region of the substrate. In the sixth layer 116, the sixth layer circuit 116C including the power-related circuit 170 is formed, and the sixth conductive layer G6 is formed to surround the outer periphery of the sixth layer circuit 116C. The fifth conductive layer G5 and the sixth conductive layer G6 are connected to the second conductive layer G2, the third conductive layer G3, and the fourth conductive layer G4 by the through holes H1.

Thus, the multilayer substrate 110A according to the second embodiment has more layers than the first embodiment, and can ensure a space where circuits are to be disposed in the sixth layer 116. Therefore, the motor drive circuit 150A can be mounted at high density and the power-related circuit 170 can be provided in a wide area, so that a high drive current can be supplied. The common ground pattern 100c is provided over the entire region of the substrate in the fifth layer 115, and surrounds the power-related circuit 170 in the fourth layer 114 and the sixth layer 116 by the entire periphery of the common ground pattern 100c, and therefore it is possible to effectively block noise radiation from the power-related circuit 170 to the outside. Therefore, it is possible to improve the EMC performance while suppressing an increase in costs.

In the second embodiment, the power-related circuit 170 included in each of the third layer circuit 113C, the fourth layer circuit 114C, and the sixth layer circuit 116C is disposed in the second region 102 of the multilayer substrate 110. In the third layer 113, as in the first embodiment, the noise guard portion G32 extends along the substrate outer edge of the second region 102, and both ends of the noise guard portion G32 are connected to portions (the third conductive layer main body G31) of the third conductive layer G3 formed in the first region 101. In the fourth layer 114 and the sixth layer 116, the noise guard portion G42 of the fourth conductive layer G4 and the noise guard portion G62 of the sixth conductive layer G6 extend along the substrate outer edge of the second region 102 at positions overlapping with the noise guard portion G32. The plurality of through holes H1 arranged along the substrate outer edge of the second region 102, are provided.

With such a pattern arrangement, the common ground pattern 100c can be provided over a wide area in the first region 101 in each layer (the first layer 111, the third layer 113, the fourth layer 114, and the sixth layer 116) in which the motor drive circuit 150A is formed. In the second region 102, since the space on the outer periphery of the power-related circuit 170 is narrow, it is not possible to provide a wide common ground pattern 100c. However, the common ground pattern 100c is formed to surround the power-related circuit 170 by the entire periphery of the common ground pattern 100c, and the common ground pattern 100c of the upper and lower layers are connected to each other by the through holes H1. Therefore, noise radiation to the outside can be effectively suppressed.

### Other Embodiments

In each of the above embodiments, an example has been illustrated in which the motor 10 is used for the pump device 1. However, the present invention may be applied to a motor to be mounted in other equipment.

### DESCRIPTION OF REFERENCE NUMERALS

1 . . . Pump device
2 . . . Case
3 . . . Stator
4 . . . Rotor
5 . . . Support shaft
6 . . . Housing
10 . . . Motor
11 . . . Radial bearing
12 . . . Thrust bearing
18 . . . Cover
19, 19A . . . Motor drive circuit substrate
20 . . . Pump chamber
21 . . . Suction pipe
22 . . . Discharge pipe
23 . . . Wall surface
25 . . . Impeller
26 . . . Disk
27 . . . Support portion
28 . . . Tubular portion
29 . . . Side wall
31 . . . Stator core
32, 33 . . . Insulator
35 . . . Coil
40 . . . Cylindrical portion
45 . . . Flange portion
47 . . . Magnet
60 . . . Resin sealing member
61 . . . First partition portion
62 . . . Second partition portion
63 . . . Bottom wall
64 . . . End portion
66 . . . Body portion
69 . . . Connector housing
71 . . . Winding terminal
75 . . . Connector terminal
100 . . . Ground pattern
100c . . . Common ground pattern
101 . . . First region
102 . . . Second region
103 . . . Third region
104 . . . Fourth region
110, 110A . . . Multilayer substrate
111 . . . First layer
111C . . . First layer circuit
112 . . . Second layer
113 . . . Third layer
113C . . . Third layer circuit
114 . . . Fourth layer
114C . . . Fourth layer circuit
115 . . . Fifth layer
116 . . . Sixth layer
116C . . . Sixth layer circuit
122 to 126, 128 . . . Capacitor
131, 132 . . . Output line
133 . . . Control signal line
134 . . . FG output line
135 . . . Drive voltage line
136 . . . First line
137 . . . Second line
138 . . . Third line
140 . . . Common line
141 to 146 . . . Filter
150, 150A . . . Motor drive circuit
151 to 153 . . . Capacitor
160 . . . Signal-related circuit
161 . . . Motor control unit
165 . . . Neutral point
170 . . . Power-related circuit
180 . . . Electronic element for noise countermeasure
181 . . . Inductor
182 . . . Diode
190 . . . Terminal hole
191 . . . First terminal hole
192 . . . Second terminal hole
193 . . . Third terminal hole
194 . . . Fourth terminal hole
195 . . . Terminal hole
196 . . . Straight portion
197 . . . Notch (screw fixing portion)
199 . . . Notch
261 . . . Blade
311 . . . Annular portion
312 . . . Salient pole
645 . . . Protrusion
751 . . . Constant voltage terminal
752 . . . First signal terminal
753 . . . Second signal terminal
754 . . . Ground terminal
C1 . . . First capacitor
C2 . . . Second capacitor
C3 . . . Third capacitor
C4 . . . Fourth capacitor
C5 . . . Fifth Capacitor
D31 to D33 . . . Diode
G1 . . . First conductive layer
G12 . . . Noise guard portion
G2 . . . Second conductive layer
G3 . . . Third conductive layer
G31 . . . Third conductive layer main body
G32 . . . Noise guard portion
G4 . . . Fourth conductive layer
G42 . . . Noise guard portion
G5 . . . Fifth conductive layer
G6 . . . Sixth conductive layer
G62 . . . Noise guard portion
H1 . . . Through hole
H2 . . . Through hole for connector
L . . . Rotation axis
L1 . . . One side in axial direction
L2 . . . Other side in axial direction
O . . . Center of multilayer substrate
P . . . Virtual line
Q1 to Q6 . . . Switching element
Q7 . . . NOT gate
R1, R2, R3 . . . Resistor
R11 to R16, R21 to R26, R31 to R34 . . . Resistor
Rs . . . Shunt resistor
S1 . . . First surface
S2 . . . Second surface

1. A motor drive circuit substrate, including:
a motor drive circuit disposed in a multilayer substrate, the motor drive circuit comprising:
a power-related circuit, including a switching element that outputs a drive current; and
a signal-related circuit, including a control element that supplies a signal to the switching element,
wherein
in the multilayer substrate, a common ground pattern is provided by integrating a ground pattern for the power-related circuit and a ground pattern for the signal-related circuit,
the multilayer substrate includes four layers stacked in an order of a first layer, a second layer, a third layer, and a fourth layer,
the common ground pattern includes a second conductive layer provided in the second layer, a third conductive layer provided in the third layer, and a fourth conductive layer provided in the fourth layer,
the first layer includes at least the control element mounted therein,
the second layer includes the second conductive layer formed over a substrate entire region,
the third layer includes a third layer circuit including the power-related circuit formed therein and the third conductive layer formed therein to surround an outer periphery of the third layer circuit by an entire periphery of the third conductive layer,
the fourth layer includes a fourth layer circuit including the power-related circuit formed therein and the fourth conductive layer formed therein to surround an outer periphery of the fourth layer circuit by an entire periphery of the fourth conductive layer,
the third conductive layer includes a noise guard portion extending along an outer periphery of the power-related circuit, and
the noise guard portion is connected to the second conductive layer and the fourth conductive layer by a plurality of through holes arranged to surround the power-related circuit.

2. The motor drive circuit substrate according to claim 1, wherein
a plurality of terminal holes into which a plurality of terminals for external connection are fitted are arranged along a substrate outer edge in a first region on one side with respect to a center of the multilayer substrate,
the power-related circuit in the third layer circuit is disposed in a second region on a side opposite to the first region with respect to the center of the multilayer substrate,
the noise guard portion extends along a substrate outer edge of the second region, both ends of the noise guard portion are connected to portions of the third conductive layer formed in the first region, and
the plurality of through holes are arranged along the substrate outer edge of the second region.

3. The motor drive circuit substrate according to claim 1, wherein
the multilayer substrate includes six layers stacked in an order of the first layer, the second layer, the third layer, the fourth layer, a fifth layer, and a sixth layer,
the common ground pattern includes a fifth conductive layer provided in the fifth layer and a sixth conductive layer provided in the sixth layer,
the fifth layer includes the fifth conductive layer formed over a substrate entire region,
the sixth layer includes a sixth layer circuit including the power-related circuit formed therein and the sixth conductive layer formed therein to surround an outer periphery of the sixth layer circuit by an entire periphery of the sixth conductive layer, and
the fifth conductive layer and the sixth conductive layer are connected to the second conductive layer, the third conductive layer, and the fourth conductive layer by the plurality of through holes.

4. The motor drive circuit substrate according to claim 3, wherein
a plurality of terminal holes into which a plurality of terminals for external connection are fitted are arranged along a substrate outer edge in a first region on one side with respect to a center of the multilayer substrate,
the power-related circuit in each of the third layer circuit, the fourth layer circuit, and the sixth layer circuit is disposed in a second region on a side opposite to the first region with respect to the center of the multilayer substrate,
in the third layer, the noise guard portion extends along a substrate outer edge of the second region, and both ends of the noise guard portion are connected to portions of the third conductive layer formed in the first region,
in the fourth layer, a portion of the fourth conductive layer overlapping with the noise guard portion extends along the substrate outer edge of the second region,
in the sixth layer, a portion of the sixth conductive layer overlapping with the noise guard portion extends along the substrate outer edge of the second region, and
the plurality of through holes are arranged along the substrate outer edge of the second region.

5. The motor drive circuit substrate according to claim 1, wherein
the motor drive circuit includes an electronic element for noise countermeasure,
the electronic element for noise countermeasure includes an inductor, and
the common ground pattern is formed in a region excluding a region overlapping with the inductor in each layer of the multilayer substrate.

6. The motor drive circuit substrate according to claim 5, wherein
the electronic element for noise countermeasure includes a first capacitor and a second capacitor, and
the first capacitor and the second capacitor connect a drive voltage line connected with the inductor in series, to the common ground pattern at two locations on a power supply side and on a side of the switching element with respect to the inductor.

7. The motor drive circuit substrate according to claim 6, wherein
the electronic element for noise countermeasure includes a third capacitor having a smaller capacity than the first capacitor,
the first capacitor is disposed on the power supply side with respect to the inductor, and
the third capacitor connects the drive voltage line to the common ground pattern on the power supply side with respect to the first capacitor.

8. The motor drive circuit substrate according to claim 6, wherein
the electronic element for noise countermeasure includes a fourth capacitor having a smaller capacity than the second capacitor,
the second capacitor is disposed on the side of the switching element with respect to the inductor, and
the fourth capacitor connects the drive voltage line to the common ground pattern on the side of the switching element with respect to the second capacitor.

9. The motor drive circuit substrate according to claim 1, wherein
a fixing portion in which a fixing member to fix the multilayer substrate is disposed and a terminal soldering portion to which a terminal for external connection is soldered are provided in an outer edge of the multilayer substrate, and
a through hole for a connector through which a connector pin is inserted and removed is provided between the fixing portion and the terminal soldering portion in the outer edge of the multilayer substrate.

10. A motor comprising:
the motor drive circuit substrate according to claim 1; and
a coil, supplied with a drive current output from the motor drive circuit substrate.

11. A pump device comprising:
the motor according to claim 10; and
an impeller, rotationally driven by the motor.
